(19) United States
(12) Patent Application Publication
(10) Pub. No.: US 2026/0007000 A1
(43) Pub. Date: Jan. 1, 2026

(54) DISPLAY DEVICE AND MOTHERBOARD

(71) Applicant: Japan Display Inc., Tokyo (JP)

(72) Inventors: Keisuke IZUMI, Tokyo (JP); Hideyuki TAKAHASHI, Tokyo (JP); Yasuhito ARUGA, Tokyo (JP)

(73) Assignee: Japan Display Inc., Tokyo (JP)

(21) Appl. No.: 19/245,464

(22) Filed: Jun. 23, 2025

(30) Foreign Application Priority Data
Jun. 27, 2024 (JP) 2024-103984

(51) Int. Cl. H10K 59/122; H10K 59/131; H10K 59/80

(52) U.S. Cl. CPC H10K 59/122; H10K 59/131; H10K 59/8793

(57) ABSTRACT

A display device includes a substrate, a display area displaying an image, a surrounding area provided on an external side relative to the display area, a partition having a lower portion located above the substrate and provided in the surrounding area and an upper portion provided on the lower portion and protruding beyond a side surface of the lower portion, and a vernier provided in the surrounding area and provided between the substrate and the partition. The partition has a first partition and a second partition adjacent to each other in a first direction. The vernier has a plurality of scale lines extending in the first direction and arranged with uniform pitch in a second direction intersecting the first direction.

### CROSS-REFERENCE TO RELATED APPLICATIONS

This application is based upon and claims the benefit of priority from Japanese Patent Application No. 2024-103984, filed Jun. 27, 2024, the entire contents of which are incorporated herein by reference.

### FIELD

Embodiments described herein relate generally to a display device and a motherboard.

### BACKGROUND

Recently, a display device with an organic light-emitting diode (OLED) applied thereto as a display element has been put into practical use. This type of display devices requires advanced quality control.

### BRIEF DESCRIPTION OF THE DRAWINGS

FIG. 1 is an illustration showing a

configuration example of a display device according to the present embodiment.

FIG. 2 is a schematic plan view showing an example of layouts of subpixels.

FIG. 3 is a schematic cross-sectional view of the display device along the III-III line of FIG. 2.

FIG. 4 is an enlarged view of the area surrounded by the chained frame IV of FIG. 1.

FIG. 5 is the schematic cross-sectional view of the display device along the V-V line of FIG. 4.

FIG. 6 is a schematic plan view of a motherboard according to the embodiment.

FIG. 7 is a schematic plan view of a panel unit.

FIG. 8 is an enlarged view of the area surrounded by the chained frame VIII in FIG. 7.

FIG. 9 is a plan view of a surrounding area

according to a comparative example.

### DETAILED DESCRIPTION

In general, according to one embodiment, a display device includes a substrate, a display area displaying an image, a surrounding area provided on an external side relative to the display area, a partition having a lower portion located above the substrate and provided in the surrounding area and an upper portion provided on the lower portion and protruding beyond a side surface of the lower portion, and a vernier provided in the surrounding area and provided between the substrate and the partition. The partition has a first partition and a second partition adjacent to each other in a first direction. The vernier has a plurality of scale lines extending in the first direction and arranged with uniform pitch in a second direction intersecting the first direction. At least some of the plurality of scale lines are located between the first partition and the second partition in the first direction.

In general, according to one embodiment, a motherboard includes a substrate, a plurality of panel units each including a display area, a surrounding area provided on an external side relative to the display area, and a margin area covering the surrounding area, a partition having a lower portion located above the substrate and provided in the surrounding area and an upper portion provided on the lower portion and protruding beyond a side surface of the lower portion, and a vernier provided across the surrounding area and the margin area and provided between the substrate and the partition. The partition has a first partition and a second partition adjacent to each other in a first direction. The vernier has a plurality of scale lines extending in the first direction and arranged with uniform pitch in a second direction intersecting the first direction. At least some of the plurality of scale lines are located between the first partition and the second partition in the first direction.

The embodiments can provide a display device and a motherboard capable of shortening measurement time.

Embodiments will be described with reference to the accompanying drawings.

The disclosure is merely an example, and proper changes in keeping with the spirit of the disclosure, which are easily conceivable by a person of ordinary skill in the art, come within the scope of the disclosure as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the disclosure. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction along the X-axis is referred to as an X-direction (a second direction), a direction along the Y-axis is referred to as a Y-direction (a first direction), and a direction along the Z-axis is referred to as a Z-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

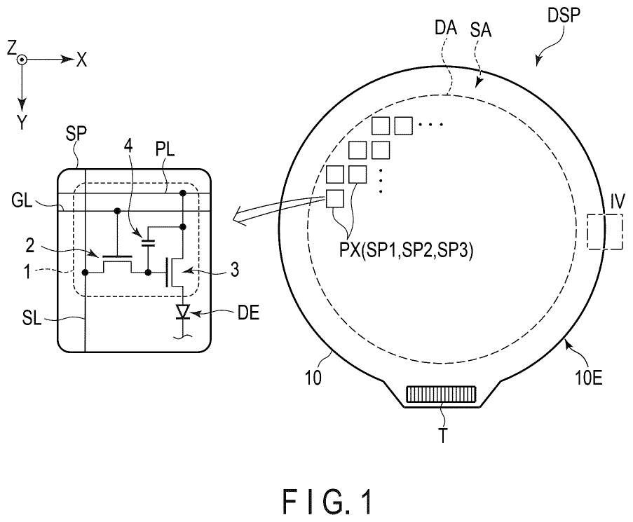

FIG. 1 is a diagram showing a configuration example of a display device DSP according to the present embodiment. The display device DSP comprises an insulating substrate 10. The substrate 10 has a display area DA which displays an image and a surrounding area SA around the display area DA. The substrate 10 may be glass or a resinous film having flexibility. The substrate 10 has an outer shape line 10E surrounding the substrate 10 and corresponding to the outer shape of the substrate 10.

In the present embodiment, the substrate 10 has an approximately circular shape as seen in plan view. The shape of the substrate 10 in a plan view is not limited to the approximately circular shape and may be another shape such as a rectangular shape, a square shape, or an elliptic shape.

The display area DA comprises a plurality of pixels PX arrayed in matrix in the X-direction and the Y-direction. Each pixel PX includes a plurality of subpixels SP that display different colors. The present embodiment assumes a case where each pixel PX includes a green subpixel SP1, a red subpixel SP2 and a blue subpixel SP3. Each of the pixels PX may include subpixels SP of other colors such as a white color together with the subpixels SP1, SP2, and SP3 or instead of any of the subpixels SP1, SP2, and SP3.

The display device DSP further comprises a terminal portion T provided in the surrounding area SA. For example, a flexible printed circuit, which applies voltage and signals for driving the display device DSP is connected to the terminal portion T.

Each subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

In the display area DA, a plurality of scanning lines GL, which supply the pixel circuit 1 of each subpixel SP with scanning signals, a plurality of signal lines S, which supply the pixel circuit 1 of each subpixel SP with video signals, and a plurality of power lines PL are provided. In the example of FIG. 1, the scanning lines GL and the power lines PL extend in the X-direction, and the signal lines SL extend in the Y-direction.

The gate electrode of the pixel switch 2 is connected to the scanning line GL. The source electrode of the pixel switch 2 is connected to the signal line SL. The drain electrode of the pixel switch 2 is connected to the gate electrode of the drive transistor 3 and the capacitor 4. The source electrode of the drive transistor 3 is connected to the power line PL and the capacitor 4. The drain electrode of the drive transistor 3 is connected to the display element DE.

The configuration of the pixel circuit 1 is not limited to the example shown in the figure. For example, the pixel circuit 1 may comprise more thin-film transistors and capacitors.

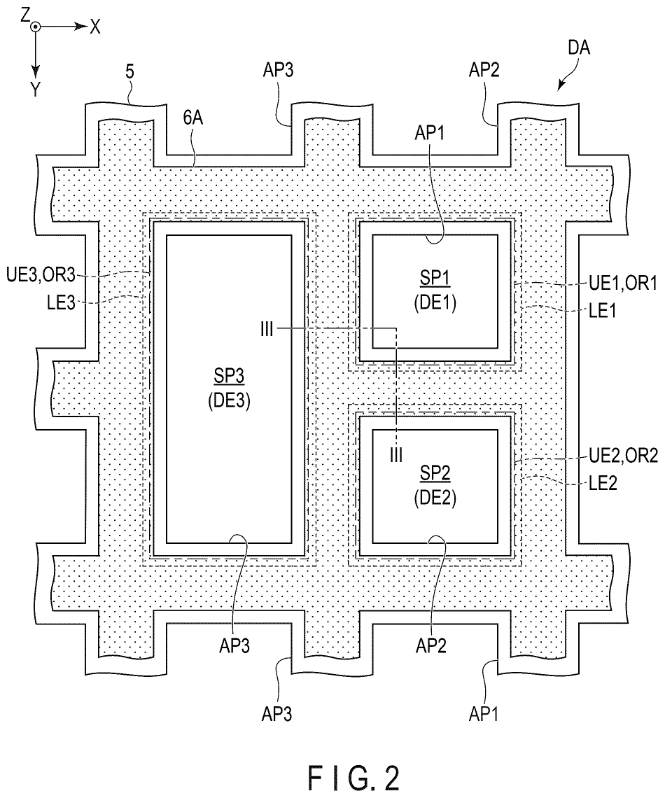

FIG. 2 is a schematic plan view showing an example of the layout of subpixels SP1, SP2, and SP3. In the example of FIG. 2, each of subpixels SP1 and SP2 is adjacent to the subpixel SP3 in the X-direction. Further, the subpixels SP1 and SP2 are arranged in the Y-direction. When the subpixels SP1, SP2, and SP3 are

arranged in this layout, in the display area DA, a column in which the subpixels SP1 and SP2 are alternately arranged in the Y direction and a column in which the plurality of subpixels SP3 are repeatedly arranged in the Y direction are formed. These columns are alternately arranged in the X-direction. The layout of subpixels SP1, SP2, and SP3 is not limited to the example of FIG. 2.

A rib layer 5 is provided in the display area DA. The rib layer 5 has pixel apertures AP1, AP2 and, AP3 in the subpixels SP1, SP2, and SP3, respectively. In the example of FIG. 2, the pixel apertures AP1 and AP2 have rectangular shapes of the same size in plan view. On the other hand, the pixel aperture AP3 is a rectangle elongated in the Y-direction relative to the pixel apertures AP1 and AP2. The size and the shape of each of the pixel apertures AP1, AP2, and AP3 is not limited to this example.

The subpixel SP1 comprises a lower electrode LE1, an upper electrode UE1, and an organic layer OR1 each overlapping the pixel aperture AP1. The subpixel SP2 comprises a lower electrode LE2, an upper electrode UE2, and an organic layer OR2 each overlapping the pixel aperture AP2. The subpixel SP3 comprises a lower electrode LE3, an upper electrode UE3, and an organic layer OR3 each overlapping the pixel aperture AP3.

Portions that overlap the pixel aperture AP1 of the lower electrode LE1, the upper electrode UE1, and the organic layer OR1 constitute a display element DE1 of the subpixel SP1. Portions that overlap the pixel aperture AP2 of the lower electrode LE2, the upper electrode UE2, and the organic layer OR2 constitute a display element DE2 of the subpixel SP2. Portions that overlap the pixel aperture AP3 of the lower electrode LE3, the upper electrode UE3, and the organic layer OR3 constitute a display element DE3 of the subpixel SP3. The display elements DE1, DE2, and DE3 may further include a cap layer to be described below. The rib layer 5 surrounds each of these display elements DE1, DE2, and DE3.

A conductive partition 6A is provided in the display area DA. The partition 6A is located above the rib layer 5 to entirely overlap the rib layer 5. In the example of FIG. 2, the partition 6A has the planar shape similar to that of the rib layer 5. That is, the partition 6A includes an aperture in each of the subpixels SP1, SP2, and SP3. From another viewpoint, each of the rib layer 5 and the partition 6A has a grating shape in plan view and surrounds each of the display elements DE1, DE2, and DE3. The partition 6A functions as lines that supply the upper electrodes UE1, UE2, and UE3 with common voltage.

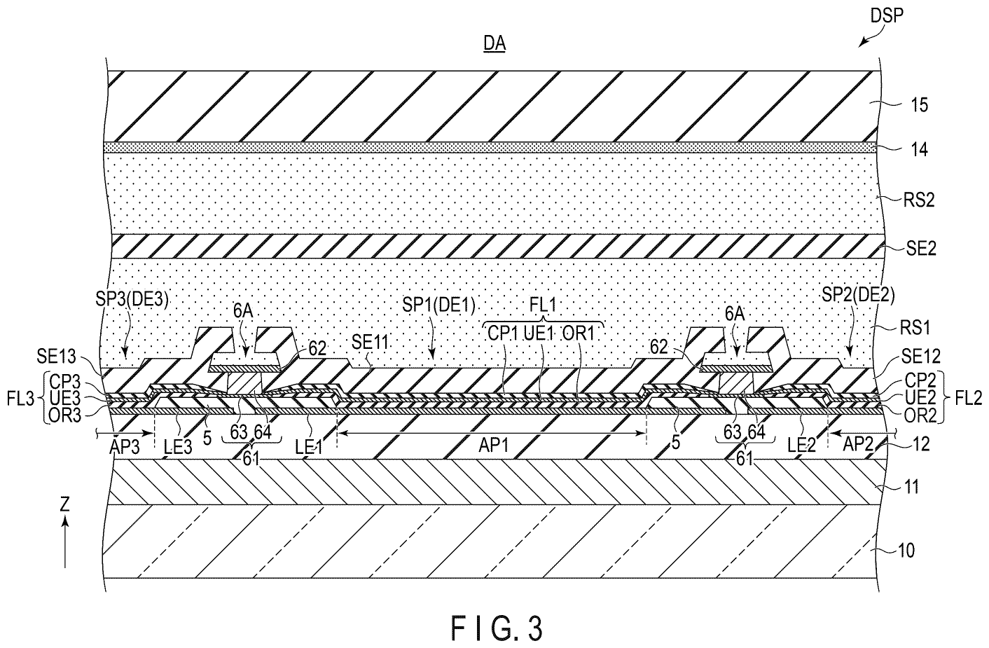

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, the scanning lines GL, the signal lines SL, and the power lines PL shown in FIG. 1. The circuit layer 11 is covered with an organic insulating layer 12. The organic insulating layer 12 functions as a planarization film, which planarizes the irregularities formed by the circuit layer 11.

The lower electrodes LE1, LE2, and LE3 are provided on the organic insulating layer 12. The rib layer 5 is provided on the organic insulating layer 12 and the lower electrodes LE1, LE2, and LE3. End portions of the lower electrodes LE1, LE2, and LE3 are covered with the rib layer 5. Although not shown in the section in FIG. 3, the lower electrodes LE1, LE2, and LE3 are connected to the respective pixel circuits 1 (the drain electrode of the drive transistor 3 shown in FIG. 1) of the circuit layer 11 through respective contact holes provided in the organic insulating layer 12.

The partition 6A includes a conductive lower portion 61 provided on the rib layer 5 and an upper portion 62 provided on the lower portion 61. The upper portion 62 has a width greater than that of the lower portion 61. This configuration allows the both end portions of the upper portion 62 to protrude beyond the side surfaces of the lower portion 61. This shape of the partition 6A is referred to as an overhang shape.

In the example of FIG. 3, the lower portion 61 has a bottom layer 63 provided on the rib layer 5 and a stem layer 64 provided on the bottom layer 63. For example, the bottom layer 63 is formed to be thinner than the stem layer 64. In the example of FIG. 3, the both end portions of the bottom layer 63 protrude beyond the side surfaces of the stem layer 64. Further, the both end portions of the bottom layer 63 are located between the end portion of the upper portion 62 and the side surface of the stem layer 64 in plan view. The upper portion 62 is provided on the stem layer 64.

The organic layer OR1 covers the lower electrode LE1 through the pixel aperture AP1. The upper electrode UE covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the side surface of the lower portion 61 of the partition 6A.

The display element DE1 includes a cap layer CP1, which covers the upper electrode UE1. The display element DE2 includes a cap layer CP2, which covers the upper electrode UE2. The display element DE3 includes a cap layer CP3, which covers the upper electrode UE3. The cap layers CP1, CP2, and CP3 function as optical adjustment layers, which improve the extraction efficiency of the light emitted from the organic layers OR1, OR2, and OR3, respectively.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

Sealing layers SE11, SE12, and SE13, which respectively cover the stacked films FL1, FL2, and FL3 are respectively provided in the subpixels SP1, SP2, and SP3. The sealing layer SE11 continuously covers the display element DE1 and the partition 6A around the display element DE1. The sealing layer SE12 continuously covers the display element DE2 and the partition 6A therearound. The sealing layer SE13 continuously covers the display element DE3 and the partition 6A therearound.

In the example of FIG. 3, the sealing layer SE11 located on the partition 6A between the subpixels SP1 and SP2 is spaced apart from the sealing layer SE12 located on this partition 6A. In the example of FIG. 3, the sealing layer SE11 located on the partition 6A between the subpixels SP1 and SP3 is spaced apart from the sealing layer SE13 located on this partition 6A. Any two of the sealing layers SE11, SE12, and SE13 may contact each other above the partition 6A.

For example, a gap is formed between each of the sealing layers SE11, SE12, and SE13 and the upper portion 62 of the partition 6A. The stacked films FL1, FL2, and FL3 may be provided in at least part of these gaps.

The sealing layers SE11, SE12, and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A polarizer 15 is provided above the resin layer RS2. In the example shown in FIG. 3, the polarizer 15 is bonded to the upper surface of the resin layer RS2 via the adhesion layer 14. The polarizer 15 covers the entire display area DA. Adhesives such as optical clear adhesive (OCA) can be used as the adhesive layer 14.

The organic insulating layer 12 is formed of an organic insulating material such as polyimide. Each of the rib layer 5 and the sealing layers SE11, SE12, SE13, and SE2 is formed of an inorganic insulating material, such as a silicon nitride (SiNx), a silicon oxide (SiOx), and a silicon oxynitride (SiON). For example, the rib layer 5 is formed of a silicon oxynitride, and each of the sealing layers SE11, SE12, SE13 and SE2 is formed of a silicon nitride. Each of the resin layers RS1 and RS2 is formed of, for example, a resinous material (organic insulating materials) such as an epoxy resin or an acrylic resin.

Each of the lower electrodes LE1, LE2, and LE3 has a reflective layer and a pair of conductive oxide layers covering the upper and lower surfaces of the reflective layer. The reflective layer is formed of, for example, a metal material having excellent light-reflecting properties, such as silver. Each of the conductive oxide layers can be formed of, for example, a transparent conductive oxide, such as an indium tin oxide (ITO), an indium zinc oxide (IZO), and an indium gallium zinc oxide (IGZO).

The upper electrodes UE1, UE2, and UE3 are formed of, for example, a metal material such as an alloy (MgAg) of magnesium and silver. For example, the lower electrodes LE1, LE2, and LE3 correspond to anodes, and the upper electrodes UE1, UE2, and UE3 correspond to cathodes.

Each of the organic layers OR1, OR2, and OR3 is composed of a plurality of thin films including a light emitting layer. For example, each of the organic layers OR1, OR2, and OR3 comprises a stacked layer structure consisting of a hole injection layer, a hole transport layer, an electron blocking layer, a light emitting layer, a hole blocking layer, an electron transport layer, and an electron injection layer. Each of the organic layers OR1, OR2, and OR3 may comprise another structure such as a tandem structure including a plurality of light emitting layers.

Each of the cap layers CP1, CP2, and CP3 has, for example, a stacked layer structure having a plurality of stacked transparent layers. These transparent layers may include a layer formed of an inorganic material and a layer formed of an organic material. The transparent layers have refractive indices different from one another. For example, these transparent layers have the refractive indices different from those of the upper electrodes UE1, UE2, and UE3 and the sealing layers SE11, SE12 and SE13. At least one of the cap layers CP1, CP2, and CP3 may be omitted.

For example, each of the bottom layer 63 and the stem layer 64 of the partition 6A is formed of a metal material. For the metal material of the bottom layer 63, for example, molybdenum (Mo), titanium (Ti), a titanium nitride (TiN), a molybdenum-tungsten alloy (MoW), or a molybdenum-niobium alloy (MoNb) can be used. For a metal material of the stem layer 64, for example, aluminum (Al), an aluminum-neodymium alloy (AlNd), an aluminum-yttrium alloy (AlY), or an aluminum-silicon alloy (AlSi) can be used. For example, at least one of the bottom layer 63 and the stem layer 64 may comprise a stacked layer structure in which a plurality of layers are stacked. The stem layer 64 may include a layer formed of an insulating material.

For example, the upper portion 62 of the partition 6A includes a stacked layer structure comprising a lower layer composed of a metal material and an upper layer composed of a conductive oxide. For the metal material forming the lower layer, for example, titanium, a titanium nitride, molybdenum, tungsten, a molybdenum-tungsten alloy, or a molybdenum-niobium alloy may be used. For a conductive oxide forming the top layer, for example, ITO or IZO may be used. The upper portion 62 may comprise a single-layer structure of a metal material. The upper portion 62 may further include a layer formed of an insulating material.

Common voltage is applied to the partition 6A. This common voltage is applied to each of the upper electrodes UE1, UE2, and UE3 in contact with the side surfaces of the lower portions 61. Pixel voltages according to the video signals of the signal lines SL are applied to the lower electrodes LE1, LE2, and LE3 through the respective pixel circuits 1 provided in the subpixels SP1, SP2, and SP3.

The organic layers OR1, OR2, and OR3 emit light in response to application of a voltage. More specifically, when a potential difference is formed between the lower electrode LE1 and the upper electrode UE1, the light emitting layer of the organic layer OR1 emits light of the green wavelength range. When a potential difference is formed between the lower electrode LE2 and the upper electrode UE2, the light emitting layer of the first organic layer OR2 emits light of the red wavelength range. When a potential difference is formed between the lower electrode LE3 and the upper electrode UE3, the light emitting layer of the organic layer OR3 emits light beams of the blue wavelength range.

As another example, the light emitting layers of the organic layers OR1, OR2, and OR3 may emit light of the same color (for example, white). In this case, the display device DSP may comprise a color filter that converts the light emitted from the light emitting layers into light of the color corresponding to the subpixels SP1, SP2, and SP3. In addition, the display device DSP may comprise a layer including quantum dots that are excited by the light emitted from the light emitting layers to generate the light of the colors corresponding to the subpixels SP1, SP2, and SP3.

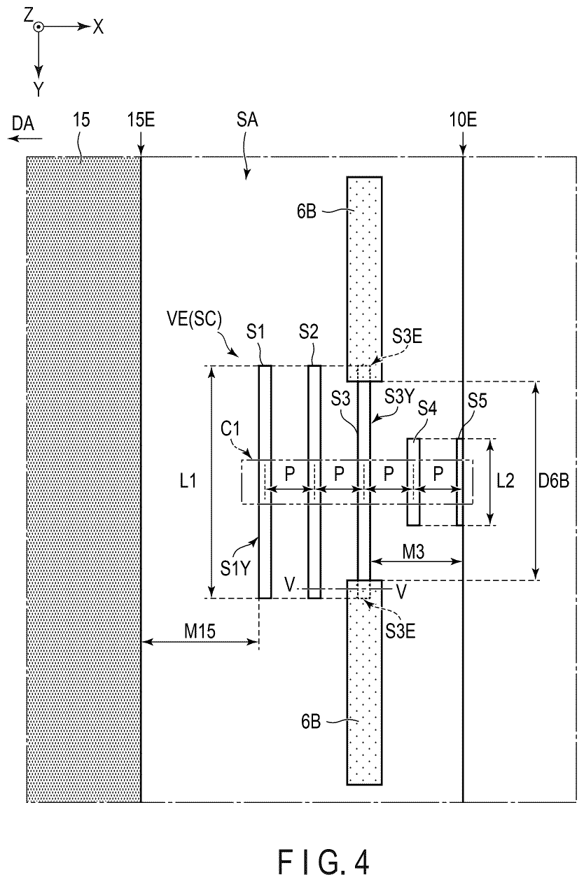

FIG. 4 is an enlarged view of the area surrounded by the chained frame IV of FIG. 1. The surrounding area SA has a plurality of partitions 6B and a vernier VE. For example, the plurality of partitions 6B are spaced apart from one another and elongated along the outer shape line 10E. In the example in FIG. 4, the plurality of partitions 6B (the first and second partitions) extend in the Y-direction and are adjacent to each other in the Y direction.

The vernier VE is located between partitions 6B adjacent to each other in the Y-direction. The vernier VE has a plurality of scale lines SC. In the example shown in FIG. 4, the plurality of scale lines SC have scale lines S1, S2, S3, S4, and S5. At least some of the plurality of scale lines SC are located between the partitions 6B adjacent to each other in the Y-direction. In the example of FIG. 4, the scale line S3 is located between the partitions 6B adjacent to each other in the Y-direction. The scale lines S1 to S5 extend in the Y-direction and are formed in rectangular shapes elongated in the Y-direction. The scale line S1 has an end portion S1Y located on the display area DA side, of end portions parallel to the Y-direction. The scale line S3 has an end portion S3Y located on the outer shape line 10E side, of end portions parallel to the Y-direction.

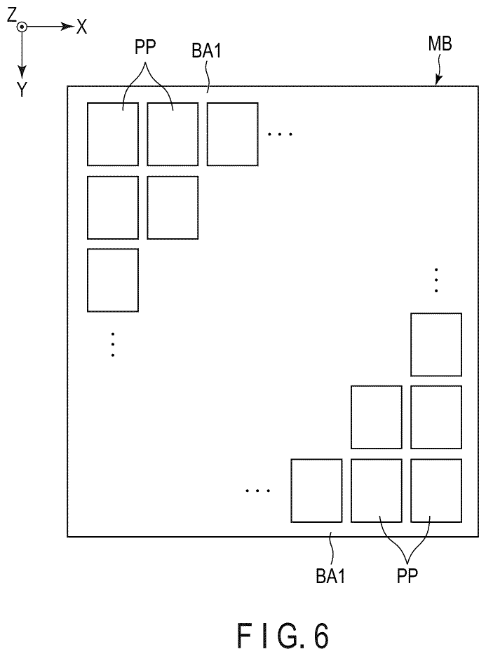

In the example shown in FIG. 4, the scale lines S1 to S4 have the same width in the X-direction. The width in the X-direction of the scale line S5 is the approximate half of the width in the X-direction of each of the scale lines S1 to S4. As described in detail later, the width in the X-direction of the scale line S5 may be different from the example shown in FIG. 4, depending on a cut position for cutting the substrate 10 from a motherboard for the display device (a motherboard MB shown in FIG. 6) along the outer shape line 10E. Further, the number of the plurality of scale lines of the vernier VE may be different from the example shown in FIG. 4, depending on the cut position. Thus, the number of the scale lines in the scale lines SC is five in the example shown in FIG. 4 but may be four or less or six or more.

The plurality of scale lines SC are arranged with uniform pitch in the X-direction. More specifically, the same pitch P is respectively between the scale lines S1 to S5. For example, the pitch P is about 25 μm.

In the example shown in FIG. 4, the scale lines S1, S2, and S3 have the same length in the Y-direction, and the scale lines S4 and S5 have the same length in the Y-direction. The length in the Y-direction of the scale lines S1, S2, and S3 (the first scale lines) is defined as a length L1 (the first length), and the length in the Y-direction of the scale lines S4 and S5 (the second scale lines) is defined as a length L2 (the second length). In this case, the length L1 is greater than the length L2 (L1>L2). The length relationship among the length in the Y-direction of the scale lines S1 to S5 is not limited to this example. For example, the scale lines S1 to S5 have the same length in the Y-direction. That is, the length L1 may be equal to the length L2 (L1=L2). For example, the scale lines S1 to S5 may have different lengths in the Y-direction. For example, the length L1 is around 220 to 240 μm, and the length L2 is around 90 to 110 μm.

The interval between the partitions 6B adjacent to each other in the Y-direction is defined as an interval D6B. In the example shown in FIG. 4, the interval D6B is smaller than the length L1 and is greater than the length L2 (L1>D6B>L2). Thus, both end portions S3E in the Y-direction of the scale line S3 overlaps each of the partitions 6B adjacent to each other in the Y-direction in plan view. Only one of the both end portions S3E may overlap the portion 6B in plan view. The interval D6B may be greater than the length L1. That is, the partition 6B may not overlap the scale lines S1 to S5 in plan view. A center portion C1 (the portion surrounded by chain lines) of each of the plurality of scale lines SC does not overlap the partition 6B in plan view. The center portion C1 is the portion that has the center in the Y-direction of each of the plurality of scale lines SC.

An end portion 15E of the polarizer 15 is located in the surrounding area SA. In the example shown in FIG. 4, the end portion 15E is located between the display area DA and the vernier VE in plan view.

A plurality of verniers VE are provided not only in the area surrounded by the chained frame IV shown in FIG. 1 but also in a plurality of areas of the surrounding area SA. An example, the vernier VE is provided on an area opposite to the display area DA with the chained frame IV interposed therebetween, an area opposite to the terminal portion T withe the display area DA interposed therebetween, and the like. When the vernier VE is provided on the area opposite to the terminal portion T with the display area DA interposed therebetween, the plurality of scale lines SC in the vernier VE of this area extend in the X-direction and are formed in a rectangular shape elongated in the X-direction.

The vernier VE is used to check a deviation amount of the actual cutting position with respect to the target cutting position when a panel unit PP to be described later of the motherboard MB is cut along a cutting line CL2. More specifically, the distance between the scale line SC and outer shape line 10E is measured. In the example shown in FIG. 4, a distance M3 in the X-direction between the end portion S3Y of the scale line S3 and the outer shape line 10E can be measured. If the actual cutting position is deviated to the right side of the figure relative to the target cutting position, the distance M3 becomes larger than a target value. On the other hand, if the actual cutting position is deviated to the left side of the figure relative to the target cutting position, the distance M3 becomes smaller than the target value. Measurement in this manner can measure the amount of deviation between the actual cut position and the target cut position.

Additionally, the vernier VE can be used to check deviation amount of an attachment position of the polarizer 15. Specifically, measurement on the distance M1 in the X-direction between the end portion 15E of the polarizer 15 and the end portion S1Y of the scale line S1 can yield the deviation amount between the actual attachment position of the polarizer 15 and the target attachment position thereof. In addition to the above examples, the vernier VE can be used for various measurements.

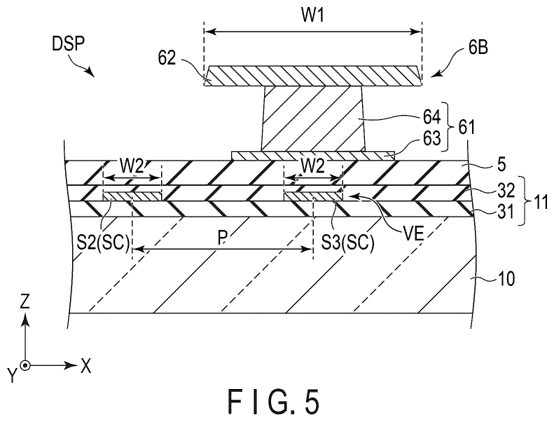

FIG. 5 is a schematic cross-sectional view of the display device DSP along the line V-V of FIG. 4. The above circuit layer 11 has inorganic insulating layer 31 and 32 provided on the substrate 10 in this order. The inorganic insulating layers 31 and 32 are formed of an inorganic insulating material such as a silicon nitride, a silicon oxide, or a silicon oxynitride. The circuit layer 11 may further include inorganic insulating layers and organic insulating layers in addition to the inorganic insulating layers 31 and 32. The inorganic insulating layer 32 is covered with the rib layer 5.

The partition 6B is provided on the rib layer 5. Similarly to the partition 6A, the partition 6B includes a lower portion 61, which includes a bottom layer 63 and a stem layer 64, and an upper portion 62. In the partition 6B as well, both end portions of the upper portion 62 protrude beyond the side surfaces of the lower portion 61. For example, each of the bottom layer 63 and the stem layer 64 of the partition 6B is formed of a metal material. For example, the upper portion 62 of the partition 6B includes a stacked layer structure with a lower layer composed of a metal material and an upper layer composed of a conductive oxide.

The vernier VE is provided between the substrate 10 and the partition 6B in the Z-direction. More specifically, a plurality of scale lines SC of the vernier VE are provided between the inorganic insulating layers 31 and 32.

The width in the X-direction of the partition 6B (the upper portion 62) is defined as a width W1, and the width in the X-direction of each of the plurality of scale lines SC is defined as a width W2. The width W2 is smaller than the width W1 (W1>W2).

For example, the plurality of scale lines SC are formed of a metal material such as titanium, aluminum, molybdenum, tungsten, a molybdenum-tungsten alloy. In the example shown in FIG. 5, the plurality of scale lines SC are formed of a molybdenum-tungsten alloy. The plurality of scale lines SC may be formed of a single-layer body or a stacked-layer body of different types of metal layers.

The plurality of scale lines SC are provided in the same layer as the scanning lines GL shown in FIG. 1 and are formed from the same material as the scanning lines GL. In other words, in the formation process of the scanning lines GL, the plurality of scale lines SC are formed at the same time as the formation of the scanning lines GL.

In the manufacturing of the display device DSP, a large motherboard is fabricated with a plurality of areas (panel portions) each corresponding to the display device DSP. The following describes a configuration applicable to this motherboard.

FIG. 6 is a schematic plan view of a motherboard MB according to the present embodiment. For example, the motherboard MB has a rectangular shape as illustrated in the figure, but may have other shapes such as a circular shape.

The motherboard MB has a plurality of panel units PP arranged in a matrix and a margin area BA1 surrounding these panel units PP. In the example of FIG. 6, the panel units PP are arranged in the X-direction and the Y-direction via the margin area BA1. The arrangement of the panel units PP in the motherboard MB is not limited to this example. As another example, some of the panel units PP may be arranged without interposing the margin area BA1.

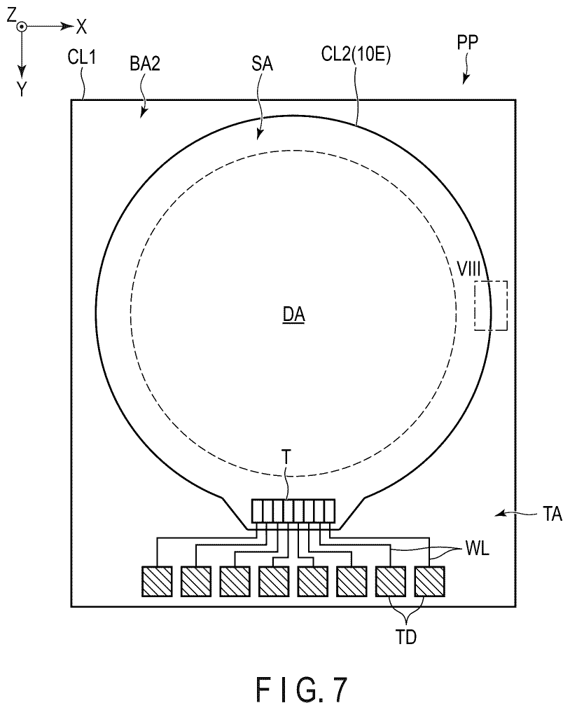

FIG. 7 is a schematic plan view of the panel unit PP. The outer shape of the panel unit PP corresponds to a cut line CL1 for cutting out each of the panel units PP from the motherboard MB.

The panel unit PP has the display area DA, the surrounding area SA, and a margin area BA2 surrounding the surrounding area SA. The cut line CL2, the outer shape of the substrate 10 of the display device DSP, is provided between the surrounding area SA and the margin area BA2. The cut line CL2 corresponds to the outer shape line 10E shown in FIG. 1. The margin area BA2 corresponds to the area between the cut lines CL1 and CL2. The surrounding area SA corresponds to the area between the display area DA and the cut line CL2.

The margin area BA2 includes an inspection area TA between the cut lines CL1 and CL2. The inspection area TA is provided with a plurality of inspection pads TD for inspecting the operation of the display panel PNL. Each of the inspection pads TD is connected to the terminal portion T via a wiring WL.

The cut line CL2 passes between the terminal portion T and each of the inspection pads TD in the vicinity of the terminal portion T. That is, the cut line CL2 traverses each wiring WL.

In the manufacturing of the display device DSP, the panel unit PP is cut out from the motherboard MB along the cut line CL1. Furthermore, this cut-out panel unit PP is subjected to the inspection using the inspection pad TD. After this inspection, the margin area BA2 is cut out from the panel unit PP along the cut line CL2.

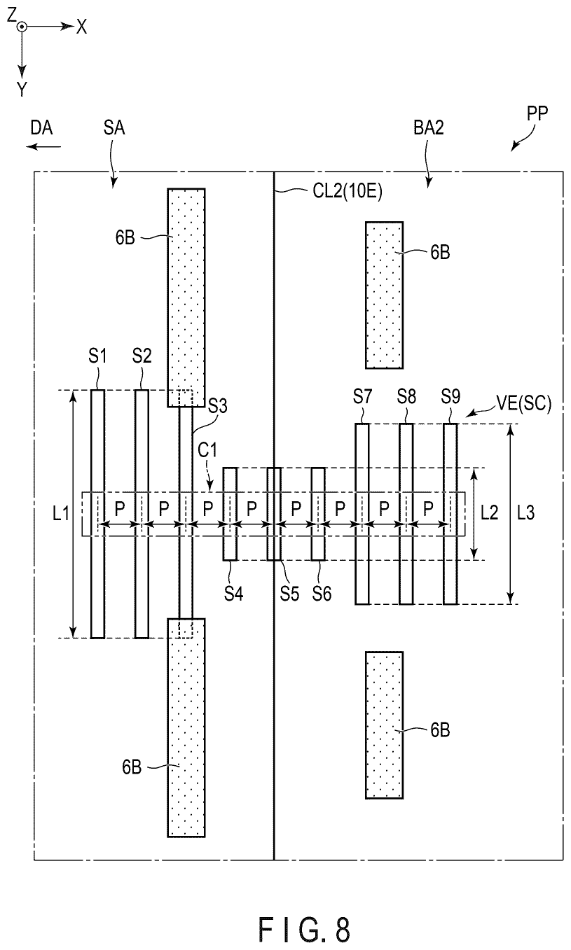

FIG. 8 is an enlarged view of the area surrounded by the chained frame VIII in FIG. 7. As in the surrounding area SA, the plurality of partitions 6B are provided in the margin area BA2. In the example shown in FIG. 8, the partition 6B in the surrounding area SA and the partition 6B in the margin area BA2 have different lengths in the Y direction. However, these partitions 6B may have the same length in the Y-direction. The vernier VE is provided across the surrounding area SA and the margin area BA2.

The plurality of scale lines SC include scale lines S1 to S9. The scale lines S1 to S9 extend in the Y-direction and are formed in rectangular shapes elongated in the Y-direction. The number of the plurality of scale lines included in the scale lines SC is not limited to the example shown in FIG. 8. The center portion C1 in the Y-direction of the plurality of scale lines SC do not overlap the partition 6B in plan view.

The scale lines S1 to S9 have the same width in the X-direction. The scale lines S1 to S9 are arranged with uniform pitch in the X direction. More specifically, the pitches P between the scale lines S1 to S9 are equal.

In the example shown in FIG. 8, the scale lines S1, S2, and S3 have the same length in the Y-direction, the scale lines S4, S5, and S6 have the same length in the Y-direction, and the scale lines S7, S8, and S9 have the same length in the Y-direction. The length in the Y-direction of the scale lines S1, S2, and S3 is defined as a length L1, the length in the Y-direction of the scale lines S4, S5, and S6 is defined as a length L2, and the length in the Y-direction of the scale lines S7, S8, and S9 is defined as a length L3. In this case, the length L3 is greater than the length L2 and smaller than the length L1 (L1>L3>L2). The relationship among the lengths in the Y direction of the scale lines S1 to S9 is not limited to this example. For example, all of the scale lines S1 to S9 may have the same length in the Y-direction. That is, the lengths L1, L2, and L3 may all be equal to one another (L1=L2=L3). For example, the scale lines S1 to S9 may have different lengths in the Y-direction. For example, the length L3 is around 150 to 170 μm.

The cut line CL2 overlaps the vernier VE. In the example shown in FIG. 8, the cut line CL2 overlaps the scale line S5. The margin area BA2 is removed by cutting the panel unit PP along the cut line CL2. After cutting the panel unit PP, the surrounding area SA remains. This configuration is the same as that shown in FIG. 4.

The position of the cut line CL2 varies depending on the cutting accuracy and positioning accuracy. Thus, the cut line CL2 does not necessarily have to overlap the scale line S5. For example, the cut line CL2 may overlap a scale line other than the scale line S5, or may be located between adjacent scale lines SC.

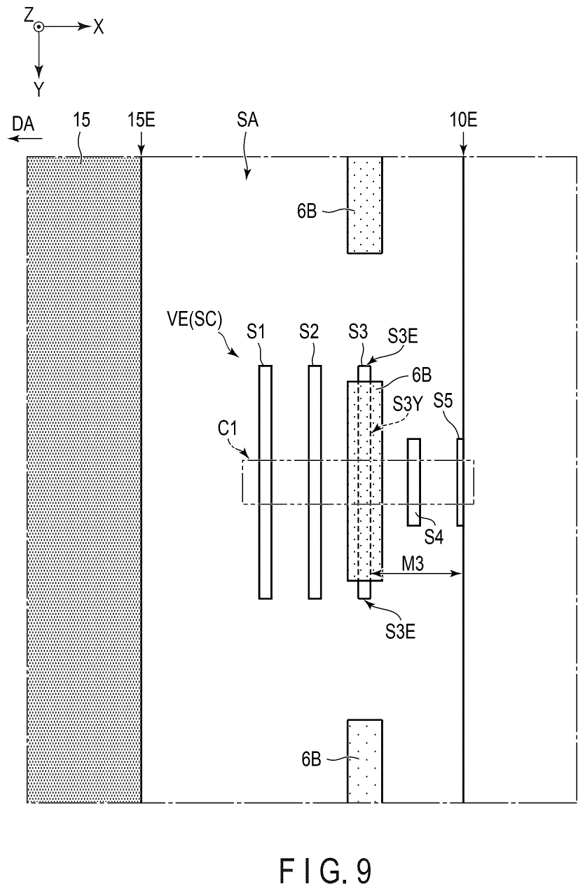

FIG. 9 is a plan view of a surrounding area SA according to a comparative example. In the example shown in FIG. 9, the partition 6B overlaps the scale line S3, and most of the scale line S3 overlaps the partition 6B. In particular, the center portion C1 overlaps the partition 6B. The partition 6B includes a layer formed of a metal material and is located above the scale line SC. This configuration makes it difficult to visually recognize the scale line S3 that overlaps the partition 6B in plan view. Thus, measurement of the distance between the scale line S3 and the outer shape line 10E involves a risk of taking time.

In the present embodiment, the vernier VE is located between the partitions 6B adjacent to each other in the Y-direction. Thus, most of the scale line SC does not overlap the partition 6B. In particular, the center portion C1 does not overlap the partition 6B. This configuration increases the visibility of the scale lines SC, facilitating the distance measurement. This results in shortening the measurement time and improving the production efficiency.

In the examples shown in FIG. 4 and FIG. 8, both end portions S3E of the scale line S3 overlap the partition 6B. Even in such a case, most of the scale line S3 does not overlap the partition 6B. Thus, the center portion C1 does not overlap the partition 6B.

Thus, this configuration hardly affects the distance measurement. In other words, some of the scale lines SC may overlap the partition 6B as long as it does not hinder the visibility of the scale lines SC. This expands the design options for the partition 6B and the vernier VE.

Furthermore, the length L1 of the scale lines S1 to S3, the length L2 of the scale lines S4 to S6, and the length L3 of the scale lines S7 to S9 are different from one another. This configuration enables immediately determining which of the plurality of scale lines SC were focused on in the measurement. This results in shortening the measurement time and improving the production efficiency.

Further, the vernier VE is located in the same layer as the scanning lines GL and is formed in the same process as the formation of the scanning lines GL. This eliminates an exclusive process for the formation of the vernier VE, shortening the manufacturing cycle. Further, the scanning line GL is thinner than the other metal layers located between the substrate 10 and the partition 6B. Therefore, even if the vernier VE is formed in the surrounding area SA, the thickness of the vernier VE has little effect on the other layers.

All of display devices and motherboards that can be implemented by a person of ordinary skill in the art through arbitrary design changes to the display device and the motherboard described above as each embodiment of the present disclosure fall within the scope of the present disclosure as long as they are in keeping with the spirit of the disclosure.

Various types of the modified examples are easily conceivable within the category of the ideas of the disclosure by a person of ordinary skill in the art and the modified examples are also considered to fall within the scope of the disclosure. For example, additions, deletions or changes in design of the constituent elements or additions, omissions, or changes in condition of the processes arbitrarily conducted by a person of ordinary skill in the art, in the above embodiments, fall within the scope of the disclosure as long as they are in keeping with the spirit of the disclosure.

In addition, the other advantages of the aspects described in the embodiments, which are obvious from the descriptions of the present specification or which can be arbitrarily conceived by a person of ordinary skill in the art, are considered to be achievable by the disclosure as a matter of course.

What is claimed is:

1. A display device, comprising:
a substrate;
a display area displaying an image;
a surrounding area provided on an external side relative to the display area;
a partition having a lower portion located above the substrate and provided in the surrounding area and an upper portion provided on the lower portion and protruding beyond a side surface of the lower portion; and
a vernier provided in the surrounding area and provided between the substrate and the partition,
the partition has a first partition and a second partition adjacent to each other in a first direction,
the vernier has a plurality of scale lines extending in the first direction and arranged with uniform pitch in a second direction intersecting the first direction, and
at least some of the plurality of scale lines are located between the first partition and the second partition in the first direction.

2. The display device of claim 1, wherein
a center portion in the first direction of each of the plurality of scale lines does not overlap the partition in plan view.

3. The display device of claim 1, wherein
a width in the second direction of each of the plurality of scale lines is smaller than a width in the second direction of the partition.

4. The display device of claim 1, wherein
the plurality of scale lines include a first scale line having a first length in the first direction and a second scale line having a second length in the first direction, the second length being smaller than the first length.

5. The display device of claim 4, wherein
an interval in the first direction between the first partition and the second partition is smaller than the first length and is greater than the second length.

6. The display device of claim 1, wherein
an interval in the first direction between the first partition and the second partition is smaller than a length in the first direction of some of the plurality of scale lines.

7. The display device of claim 1, wherein
an end portion of each of some of the plurality of scale lines overlaps the first partition in plan view.

8. The display device of claim 1, further comprising:
a polarizer located above the substrate and covering the display area, wherein
an end portion of the polarizer is located between the display area and the vernier in plan view.

9. The display device of claim 1, wherein
the plurality of scale lines are formed of metal materials.

10. The display device of claim 1, further comprising:
a plurality of scanning lines extending in the second direction in the display area, and
the plurality of scale lines are formed of the same material as the scanning lines.

11. The display device of claim 1, wherein
the upper portion has a layer formed of a metal material.

12. A motherboard, comprising:
a substrate;
a plurality of panel units each having a display area, a surrounding area on an external side relative to the display area, and a margin area surrounding the surrounding area;
a partition having a lower portion located above the substrate and provided in the surrounding area and an upper portion provided on the lower portion and protruding beyond a side surface of the lower portion; and
a vernier provided across the surrounding area and the margin area and provided between the substrate and the partition, wherein
the partition has a first partition and a second partition adjacent to each other in a first direction,
the vernier has a plurality of scale lines extending in the first direction and arranged with uniform pitch in a second direction intersecting the first direction, and
at least some of the plurality of scale lines are located between the first partition and the second partition in the first direction.

13. The motherboard of claim 12, wherein
a center portion in the first direction of each of the plurality of scale lines does not overlap the partition in plan view.

14. The motherboard of claim 12, wherein
a width in the second direction of each of the plurality of scale lines is smaller than a width in the second direction of the partition.

15. The motherboard of claim 12, wherein
the plurality of scale lines include a first scale line having a first length in the first direction and a second scale line having a second length in the first direction, the second length being smaller than the first length.

16. The motherboard of claim 12, wherein
an interval in the first direction between the first partition and the second partition is smaller than a length in the first direction of some of the plurality of scale lines.

17. The motherboard of claim 12, wherein
an end portion of each of some of the plurality of scale lines overlaps the first partition in plan view.

18. The motherboard of claim 12, wherein
the plurality of scale lines are formed of metal materials.

19. The motherboard of claim 12, further comprising:
a plurality of scanning lines extending in the second direction in the display area, and
the plurality of scale lines are formed of the same material as the scanning lines.

20. The motherboard of claim 12, wherein
the upper portion has a layer formed of a metal material.
